(19) United States
(12) Patent Application Publication
(10) Pub. No.: US 2011/0115069 A1
(43) Pub. Date: May 19, 2011

(54) ELECTRONIC DEVICE INCLUDING A PACKAGING SUBSTRATE AND AN ELECTRICAL CONDUCTOR WITHIN A VIA AND A PROCESS OF FORMING THE SAME

(76) Inventors: Serene Seoh Hian Teh, Kuala Lumpur (MY); Won Yun Sung, Seremban Nsdk (MY); Atapol Prajuckamol, Rayong (TH)

(21) Appl. No.: 12/696,897

(22) Filed: Jan. 29, 2010

(30) Foreign Application Priority Data
Nov. 13, 2009 (MY) PI 20094817

(51) Int. Cl. H01L 23/52; H01L 21/50; H01L 21/78

(52) U.S. Cl. 257/693; 438/118; 438/113; 257/E21.499; 257/E21.599; 257/E23.141

(57) ABSTRACT

An electronic device can include a packaging substrate that including an organic material and a hole extending into the packaging substrate. An electrically conductive member can include a via within the hole, and a lead lying along a major surface of the packaging substrate and electrically connected to the via. In an embodiment, the electrically conductive material can be plated, printed, or otherwise formed within and over the organic material, and a leadframe and a corresponding formation of a molding compound around the leadframe are not necessary.

### FIELD OF THE DISCLOSURE

The present disclosure relates to electronic devices and processes of forming electronic devices, and more particularly to, electronic devices including packaging substrates having electrical conductors within vias and processes of forming the same.

### RELATED ART

Packaged semiconductor devices can be formed using a packaging process in which a metal-containing leadframe is a starting material from which a plastic substrate if formed. More specifically, the leadframe can include leads that are held in place by other parts the leadframe. Therefore, all of the leads are electrically connected to one another early in the process. The leadframe is attached to a tape, and a molding compound can be formed in voids or other openings between the leads and other areas of the leadframe. The tape can be removed after the molding compound hardens. Portions of the leadframe that connect the leads to one another may be removed after the molding compound has been formed. A die can be attached to a portion of the metal leadframe and its bond pads can be wire bonded to leads of the leadframe. A molding compound can be formed over the leads, die, and wire bonds. A subsequent operation can be used to singulate the semiconductor device so that it can be tested and sold. Typically, a portion of the leadframe will be cut by a saw during the singulation operation.

FIG. 1 includes an illustration of a cross-sectional view of a packaged semiconductor device 10. The device includes a packaging substrate 110 that includes a leadframe. The leadframe 110 includes leads 112 that are electrically connected by vias 114. A solder mask overlies the packaging surface at locations where solder is not to be formed. The leads may be plated with a different metal-containing compound so that subsequently attached wires adhere better to the plated material than to the material within the leadframe. A passivation layer 118 is formed over part of the leads 112, and more particularly, over the vias 114. A die 120 is attached to the packaging substrate 110 using an adhesive compound 116. Wire bonds 122 electrically connect bond pads of the die 120 to leads 112. Note that the wire bond connections at the leads 112 are laterally offset from the vias 114. The die 120 and wires 122 are encapsulated with an encapsulant 140. Solder balls are attached to leads along the bottom leads 112 of the packaging substrate 110. The packaged semiconductor device 10 is typically one of several semiconductor devices that are processed during the same packaging operations. A saw is typically used to singulate the semiconductor devices into individual semiconductor devices. The saw typically cuts through the packaging substrate 110 and portions (not illustrated) of the leadframe.

### BRIEF DESCRIPTION OF THE DRAWINGS

Embodiments are illustrated by way of example and are not limited in the accompanying figures.

FIG. 1 includes an illustration of a cross-sectional view of a packaged semiconductor device. (Prior art)

FIG. 2 includes an illustration of a top view of a sheet of material that can be used in forming packaged semiconductor devices.

FIG. 3 includes an illustration of the sheet of FIG. 2 after making indexing and tooling holes into the sheet.

FIG. 4 includes an illustration of an expanded view of the sheet of FIG. 3 after holes for vias are formed into the sheet.

FIG. 5 includes an illustration of a top view of the sheet of FIG. 4 after forming a conductive material within the holes and over portions of a major surface of the sheet.

FIG. 6 includes an illustration of a top view of the sheet of FIG. 5 after attaching a die to the sheet and making electrical connections between the die and leads.

FIG. 7 includes an illustration of a top view of the sheet of FIG. 6 after encapsulating the die and leads.

FIGS. 8 and 9 include illustrations of a top view and a bottom view, respectively, of a packaged semiconductor device.

FIGS. 10 and 11 include illustrations of cross-sectional views packaged semiconductor devices in accordance with other embodiments.

FIG. 12 includes an expanded view of the sheet of FIG. 3 after holes for vias are formed into the sheet in accordance with another embodiment.

FIG. 13 includes an illustration of a top view of the sheet of FIG. 12 after forming a conductive material within the holes and over portions of a major surface of the sheet.

FIG. 14 includes an illustration of a top view of the sheet of FIG. 13 after attaching a die to the sheet and making electrical connections between the die and leads.

FIGS. 15 and 16 include illustrations of a top view and a bottom view, respectively, of a packaged semiconductor device.

FIG. 17 includes an illustration of a cross-sectional view of a packaged semiconductor device in accordance with another embodiment.

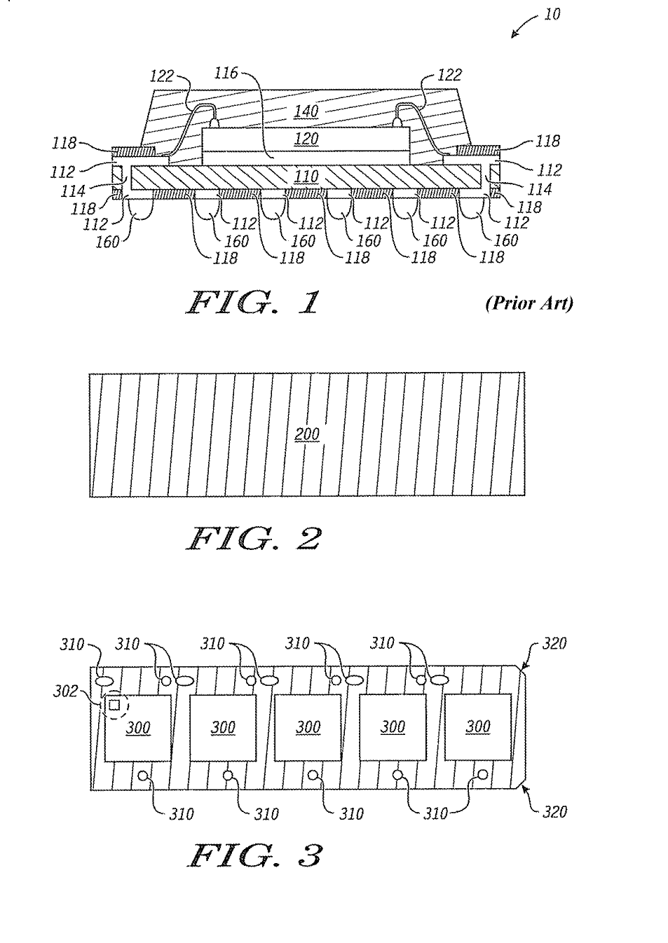

Skilled artisans appreciate that elements in the figures are illustrated for simplicity and clarity and have not necessarily been drawn to scale. For example, the dimensions of some of the elements in the figures may be exaggerated relative to other elements to help to improve understanding of embodiments of the invention.

### DETAILED DESCRIPTION

The following description in combination with the figures is provided to assist in understanding the teachings disclosed herein. The following discussion will focus on specific implementations and embodiments of the teachings. This focus is provided to assist in describing the teachings and should not be interpreted as a limitation on the scope or applicability of the teachings.

The terms “comprises,” “comprising,” “includes,” “including,” “has,” “having” or any other variation thereof, are intended to cover a non-exclusive inclusion. For example, a method, article, or apparatus that comprises a list of features is not necessarily limited only to those features but may include other features not expressly listed or inherent to such method, article, or apparatus. Further, unless expressly stated to the contrary, “or” refers to an inclusive-or and not to an exclusive-or. For example, a condition A or B is satisfied by any one of the following: A is true (or present) and B is false (or not present), A is false (or not present) and B is true (or present), and both A and B are true (or present).

Also, the use of “a” or “an” is employed to describe elements and components described herein. This is done merely for convenience and to give a general sense of the scope of the invention. This description should be read to include one or at least one and the singular also includes the plural, or vice versa, unless it is clear that it is meant otherwise. For example, when a single item is described herein, more than one item may be used in place of a single item. Similarly, where more than one item is described herein, a single item may be substituted for that more than one item.

Unless otherwise defined, all technical and scientific terms used herein have the same meaning as commonly understood by one of ordinary skill in the art to which this invention belongs. The materials, methods, and examples are illustrative only and not intended to be limiting. To the extent not described herein, many details regarding specific materials and processing acts are conventional and may be found in textbooks and other sources within the semiconductor and electronic arts.

FIG. 2 includes a top view of a sheet 200 of a material suitable for use in a packaging substrate. Portions of the sheets will become packaging substrates for semiconductor devices. The sheet 200 can include a plastic material, and in one embodiment, can include acrylonitrile butadiene styrene (“ABS”), polycarbonate, polyamide, polypropylene, polypthalamide, polyester, polyarylamide, polyacetal, polyphenylene oxide, polyetherimide, fluorine-containing polymer, epoxy molding compound, or any combination thereof.

In a particular embodiment, a combination of the materials can include ABS and polycarbonate (ABS/PC) material, a nylon material, a liquid crystal polymer, or potentially another combination of materials, such as in the form of laminated films or copolymers. In another embodiment, the sheet 200 can include a thermally conductive filler. The thermally conductive filler can include crystal silica (SiO₂), aluminum nitride (AlN), silicon nitride (Si₃N₄), silicon carbide (SiC), alumina (Al₂O₃), another suitable thermally conductive material, or any combination thereof. In a particular embodiment, a filler or other material is considered thermally conductive when its thermal conductivity is at least 1.3 W/mK.

The dimensions of the sheet 200 can vary depending upon the application. The sheet 200 can be relatively large compared to individual semiconductor devices that will be formed using parts of the sheet 200. In another embodiment, the sheet 200 can correspond to the size of an individual semiconductor device. In other embodiments, other shapes of the sheet 200 may be used while still using the concepts as described herein. Thus, from a top view, the sheet 200 can be a rectangular sheet (for example, a square sheet), a circular sheet, and elliptical-shape the sheet, or another polygon-shaped sheet. After reading this specification, skilled artisans will be able to determine the particular dimensions and shape of the sheet 200 for their particular equipment set and application.

FIG. 3 includes a top view of the sheet 200 after forming tooling holes 310 and index markers 320. The tooling holes 310 and index markers 320 can be used to assist handle of the sheet 200, and the index markers 320 may ensure that the sheet 200 is properly oriented when during processing. In the embodiment as illustrated in FIG. 3, the sheet 200 includes panels 300, wherein each panel 300 includes units, one of which is illustrated in FIG. 3 as unit 302. In other embodiments, more panels or fewer panels may be present within the sheet 200, and more units or fewer units may reside within each panel 300. The panels may be substantially identical or may differ from one another, and the units may be substantially identical or differ from one another.

FIG. 4 includes an illustration of an expanded portion of the sheet 200, and includes units 302. In this particular embodiment, many units 302 reside within the panel. Holes 400 are formed at least partly through the thickness of the sheet 200. In a particular embodiment, the holes 400 can extend from one major surface of the sheet 200 towards the opposite major surface of the sheet 200. In a particular embodiment, the holes 400 extend completely through the entire thickness of the sheet 200. In another embodiment, the holes 400 extend only partially through the thickness of the sheet 200. In a particular embodiment, a conductive member (not illustrated) may lie at an elevation between the opposing major surfaces of the sheet 200 and can be used to route connections between a subsequently attached die along one major surface of the sheet 200 to leads along the opposing major surface of the sheet 200. From a top view, such a conductive member will lie entirely within the border of the unit 302, so that a subsequent singulation operation will not require cutting through metal-containing materials. Lead areas 410 are illustrated by dashed lines and surround each of the holes 400. The lead areas 410 correspond to a final shape of a conductive material that will be subsequently formed. The paddle areas 420 are illustrated by dashed lines and correspond to areas over which dies will be subsequently attached to the sheet 200.

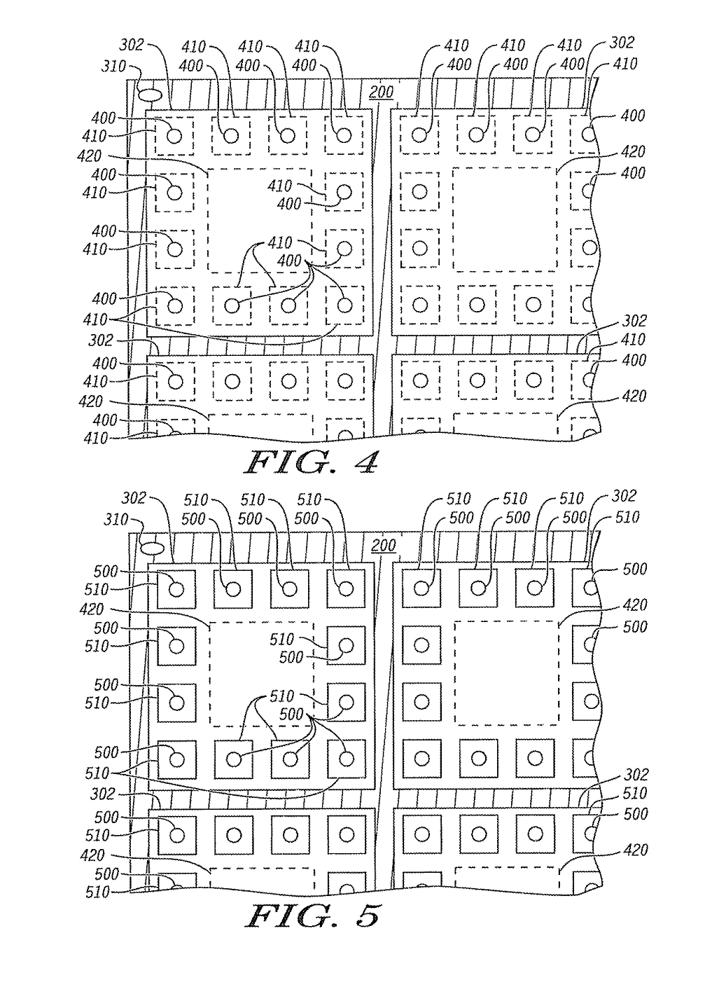

FIG. 5 includes an illustration of a top view after forming electrically conductive members including vias 500 and leads 510. Although not illustrated in FIG. 5, electrically conductive members, including vias and leads, can be formed within other holes that were previously formed and along the opposite major surface of the sheet 200. The electrically conductive members can include a metal, a metal alloy, an electrically conductive polymer, an electrically conductive ink, or any combination thereof. In a particular embodiment, the electrically conductive members can include a metal, such as copper, nickel, or a noble metal (for example, ruthenium, rhodium, palladium, silver, osmium, iridium, platinum, or gold), a metal alloy, or any combination thereof. In another embodiment, the conductive polymer or ink may be electrically conductive as deposited, such as during coating, or subsequently may be made electrically conductive.

The electrically conductive members can be formed using electroless plating, electrolytic plating, additive plating, conductive ink printing, or any combination thereof. When plating is used, plating can be performed as barrel plating or immersion plating. In an embodiment, an electrically conductive seed layer may be formed before performing a plating process. In a particular embodiment, an electrically conductive ink is printed at locations where the leads 510 are being formed. The holes, where the vias 500 are being formed, may be partially or completely filled with the electrically conductive ink. The printing can be performed such that other areas of the sheet 200 along the major surface as illustrated in FIG. 5 are not covered by the electrically conductive ink. An electroless plating process can be subsequently formed to obtain the desired thickness and conductivity of the electrically conductive members. In another particular embodiment, a seed layer is deposited by chemical or physical vapor deposition. The seed layer formation may only partly fill the holes where the vias 500 are formed. This seed layer may be formed over substantially all of the sheet 200 along the major surface as illustrated in FIG. 5. Electrolytic plating can be performed to obtain the desired thickness and conductivity of the electrically conductive members. A patterning step can be performed to achieve the shapes of the leads 510 as illustrated in FIG. 5. In yet another embodiment, the seed layer as described in the prior embodiment may be selectively formed. In a particular embodiment, the seed layer can be deposited by chemical or physical vapor deposition using a stencil mask, wherein the stencil mask includes openings where the electrically conductive members are formed. In another embodiment, the seed layer can be deposited by chemical or physical vapor deposition over substantially all of the sheet 200 along the major surface as illustrated in FIG. 5 and patterned to correspond to the locations where the leads 510 are formed, before electrolessly plating remaining portions of the electrically conductive members. After reading this specification, skilled artisans will appreciate that many different techniques can be used to form the electrically conductive members. The embodiments as described herein are merely to illustrate some embodiments and not to limit the scope of the present invention.

At this point in the process, formation of the packaging substrate is substantially complete. Die attach and other subsequent operations can be performed.

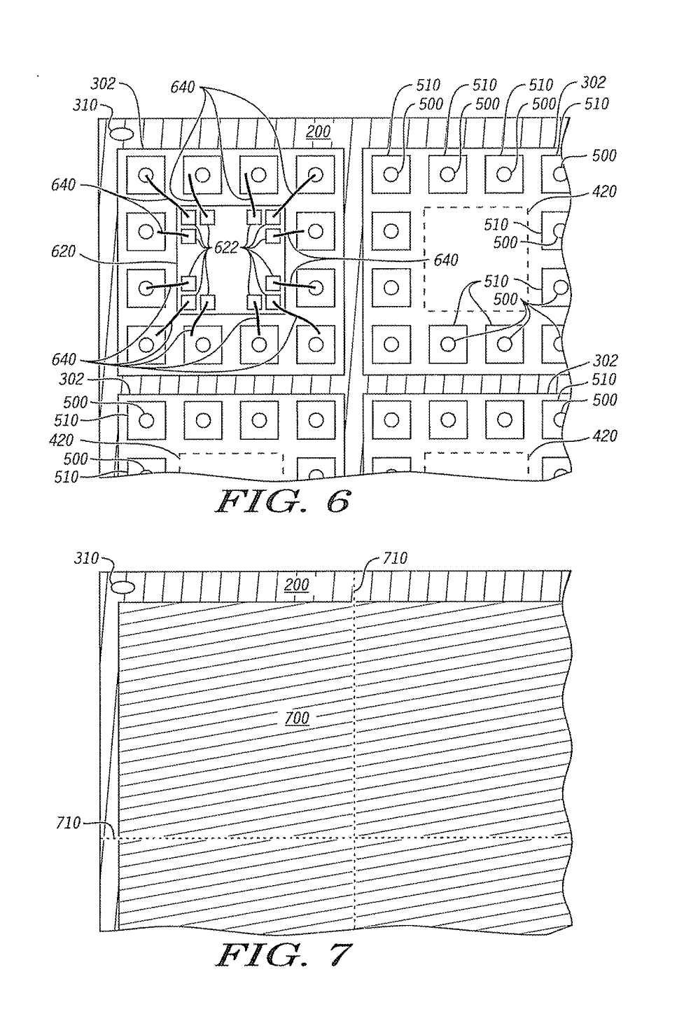

FIG. 6 includes a top view of the sheet 200 after attaching a die 620 to a major surface of the sheet 200, and electrically connecting bond pad 622 of the die 620 to the leads 510 of the packaging substrate. The die 620 can be attached with a thermally conductive material. In a particular embodiment, the thermally conductive material may also be electrically insulating. After the die 620 is attached to the sheet 200, wires 640 can be bonded between the bond pad 622 and the leads 510. As illustrated in FIG. 6, some of the wires 640 may be attached to the leads 510 directly over the vias 500 or may be attached to the leads 510 at locations laterally offset from the vias 500. The operations of attaching the die 620 and forming the wires 640 may be performed on a particular unit 302 before proceeding onto another unit 302 as illustrated in FIG. 6. In another embodiment, other die may be attached within each of the units 302 before wires 640 are bonded between the bond pad 622 and the leads 510. In still another embodiment (not illustrated), a flip-chip technique can be used. In this embodiment, electrically conductive bumps are formed over the bond pads 622, and the conductive bumps can be heated to flow solder and electrically connect the bond pads 620 leads to leads on the sheet 200.

FIG. 7 includes an illustration of the sheet 200 after forming an encapsulant 700 over the die 620 and electrically conductive members that include the vias 500 and the leads 510. The encapsulant 700 can include the same material as the sheet 200 or may include a different material. The dotted lines 710 in FIG. 7 illustrate where a singulation operation will be performed to cut or otherwise separate each unit into an individual packaged semiconductor device. The singulation can be performed using a cutting tool, such as a saw, a laser, a pressurized fluid (e.g., a water jet), or the like. In a particular embodiment, the singulation can be performed such that the cutting tool does not cut through any metals or metal alloys, and in another particular embodiment, only cuts through a plastic or other organic material. In a more particular embodiment when a saw is used, the saw blade does not require cutting through metals or metal alloys that cause the saw blade to wear faster, and therefore, the saw blade can be used significantly longer before needing to be replaced due to wear.

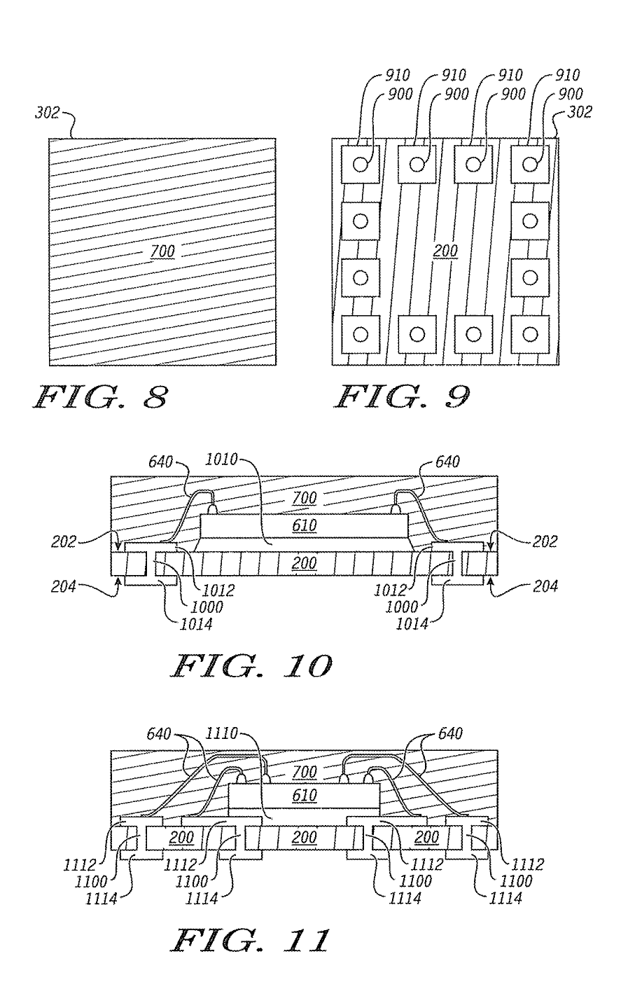

FIGS. 8 and 9 include a top view and a bottom view, respectively, of a packaged semiconductor device. In FIG. 8, only the encapsulant 700 is seen from the top view. In FIG. 9, portions of the sheet 200, vias 900, and leads 910 can be seen. The electrically conductive members that include the vias 900 and leads 910 can be formed at the same time as the vias 500 and the leads 510. In a particular embodiment, the vias 500 and 900 have substantially the same composition as compared to one another, and the leads 510 and 910 can have substantially the same composition as compared to one another. In another embodiment, the vias 900 can be formed at a different time as compared to the vias 500, and the leads 910 can be formed at a different time as compared to the leads 510. Further, vias 500 and 900 have different compositions as compared to one another, and the leads 510 and 910 can have different compositions as compared to one another. The electronic device can include the packaged semiconductor device as illustrated in FIGS. 8 and 9. In one embodiment, the electronic device can be the packaged semiconductor device. In another embodiment, the packaged semiconductor device can be part of a larger electronic device, such as a circuit board, a module, a computer, or another electronic system.

FIGS. 10 and 11 include cross-sectional views of packaged semiconductor devices to illustrate some of the features of the semiconductor devices. FIG. 10 includes the sheet 200 having the opposing major surfaces 202 and 204. The die 610 is attached to the sheet with an adhesive compound 1010. The die 610 is electrically connected to leads 1012 by the wires 640. In this particular embodiment, thru-hole vias 1000 electrically connect leads 1012 along the major surface 202 to leads 1014 along the major surface 204. In this particular embodiment, the wires 640 are electrically connected to the leads 1012 at locations laterally offset from the vias 1000.

FIG. 11 includes a cross-sectional view of a packaged semiconductor device that includes leads 1112 and 1114 that are connected to one another by vias 1100. The die 610 is attached to the sheet 200 and overlies portions of the leads 1112 with an adhesive compound 1110. In a particular embodiment, the adhesive compound 1110 can include a thermally conductive, electrically insulating material. In the embodiment as illustrated in FIG. 11, the wires 640 are connected to the leads 1112. The wires 640 between the die 610 and the outer leads 1112 are attached directly over the vias 1100. The wires 640 between the die and the inner leads 1112 are laterally offset from the vias 1100, and hence, the locations where the wires 640 are connected to the inner leads 1112 are not directly above the vias 1100.

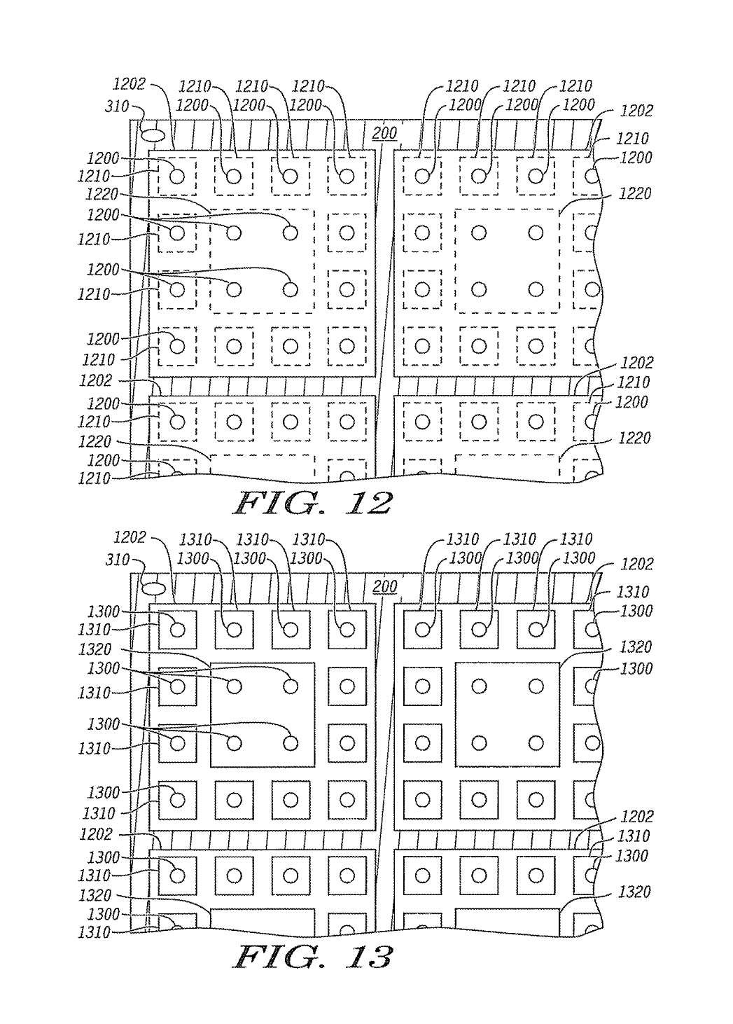

In another embodiment, as illustrated in FIGS. 12 to 16, the backside of the die can be electrically connected to a lead and be biased to a predetermined voltage at an external surface of a lead. The structures as illustrated in FIGS. 12 to 16 can be formed using any of the materials or techniques as previously described with respect to FIGS. 5 to 9. More particularly, referring to FIG. 12, holes 1200 can be formed in a manner similar to any of techniques previously described with respect to the holes 400. Note that some of the holes 1200 lie within dashed blocks 1220 that generally correspond to locations where electrically conductive paddles will be formed and a die will be subsequently attached.

FIG. 13 includes an illustration of top view the sheet 200 after forming electrically conductive members that include vias 1300, leads 1310, and electrically conductive paddles 1320. The features as illustrated in FIG. 13 can be formed using any of the materials and techniques as previously described with respect to the electrically conductive members that include the vias 500 and the leads 510. In this particular embodiment, the electrically conductive paddles 1320 will allow the backsides of subsequently-attached dies to be biased. Some of the vias 1300 allow electrically connections from the other major surface of the sheet 200 to be made to the electrically conductive paddles 1320.

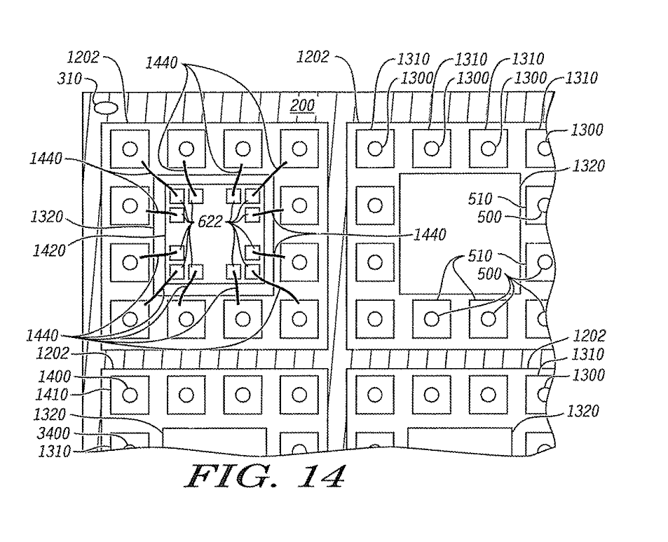

FIG. 14 includes an illustration of a top view of the sheet 200 after attaching a die 1420 and making electrical connections to some of the leads 1310 and one of the electrically conductive paddles 1320. In a particular embodiment, an electrically conductive adhesive compound can be used to attach the die 1420 to the electrically conductive paddle 1220. In a particular embodiment, wires 1440 can be bonded to the bond pads 1422 of the die 1420 and the leads 1310. The electrical connections and die attach operations can be performed using any of the previously described techniques with respect to the electrical connections in FIG. 6.

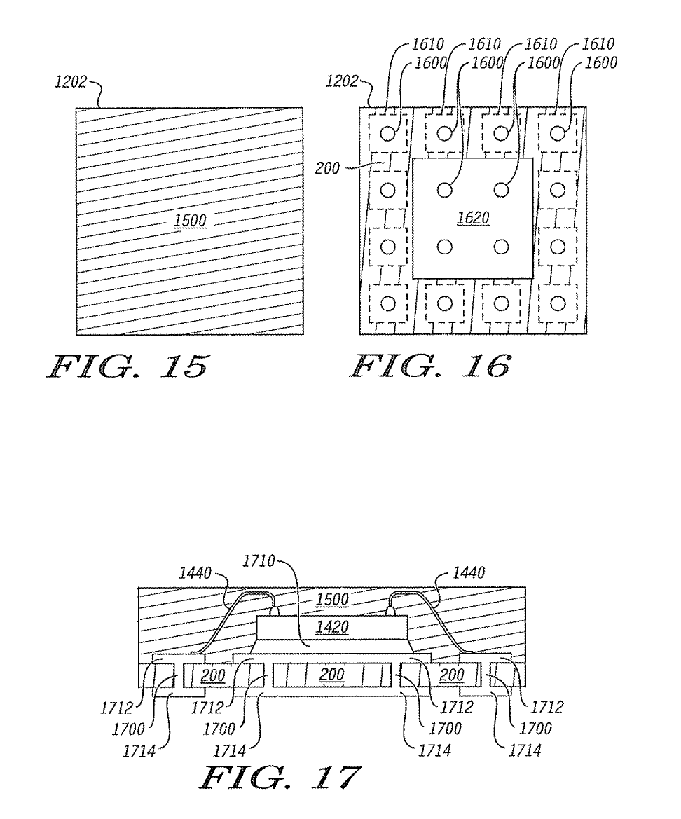

FIGS. 15 and 16 include a top view and a bottom view, respectively, after forming a substantially completed semiconductor device. An encapsulant 1500, as illustrated in FIG. 15, is formed over the die 1420, the wires 1440, and the leads 1310 (not illustrated in FIG. 15). Referring to FIG. 16, electrically conductive members including vias 1600, leads 1610, and a paddle contact 1620 allow external connections to be made to die within the packaged semiconductor device.

In another embodiment, FIG. 17 includes a cross-sectional view of a packaged semiconductor device. In this particular device, the die 1420 is attached to the lead 1712 with an electrically conductive adhesive compound 1710. Vias 1700 extend through the sheet 200 and are electrically connected to leads 1714 on the opposite side of the sheet.

The concepts as described herein are applicable to many electronic devices and are particularly well suited for semiconductor devices having plastic packaging materials. Costs can be reduced by forming leads by printed, plating, depositing, or otherwise forming conductive members, including vias and leads, at locations where such features are needed or desired. In a particular embodiment, the electrically conductive members, including vias and leads, are formed within and on a plastic or another organic substrate.

Conventional semiconductor devices can have leadframes that extend across many different semiconductor devices, and a molding compound is formed around voids and other open areas of the leadframe. Because the leadframe holds the leads in place during a molding operation to form a substrate, the process of forming conventional semiconductor devices involves significantly more metal-containing material than embodiments as described herein. More particularly, portions of a leadframe that hold adjacent leads in place for a conventional process are not needed for an embodiment as previously described because the packaging substrate is already formed before leads are formed.

Further, within the same conventional semiconductor device, the leads initially are electrically shorted to one another by the leadframe. Thus, the leads need to be electrically separated from one another before completing the formation of the semiconductor device. Separating the leads can be difficult as etching, machining, or both may be used to remove portions of the leadframe necessary to isolate the leads and an electrically conductive paddle from one another. As the pitch of the leads decreases, the lead isolation operation will continue to become more difficult.

Conventional semiconductor devices can be formed using a leadframe that extends across many different semiconductor devices. A singulation operation is used to cut through portions of the leadframe between the different semiconductor devices. An embodiment as described herein does not require a leadframe that extends between semiconductor devices. Because a metal-containing material, such as a metal or a metal alloy, can be disposed completely within individual semiconductor devices and not extend between different semiconductor devices, a singulation operation does not need to cut through such metal-containing material. In a particular embodiment, the singulation operation may cut through only plastic or other organic material(s). A saw blade may be used more times before it wears out. Further, the particular methods used for the singulation operation may be more varied. Still further, because no metal or metal alloy would be exposed at the edge of a semiconductor device, metal corrosion or oxidation may be less likely to occur. Moisture penetration into the semiconductor device may be significantly less than if a metal or metal alloy would be exposed at the edge.

A number of other steps that may need to be performed for conventional semiconductor devices having leadframes. Tape may be applied to the leadframe to hold the leadframe in place and protect external connection surfaces of the leads when a plastic molding compound is used to form the packaging substrate. The tape is subsequently removed after the packaging substrate is formed. Because forming the packaging substrate using the molding compound is a dirty step, cleaning steps are required due to the molding compound and also the use of the tape. By using embodiments described herein, the tape, including its attachment and removal and associated cleaning steps, can be eliminated.

Particular conventional semiconductor devices can include copper leadframes. The copper present at the surfaces of the leads needs to be plated with a solder material to allow proper electrical connections to be made between the leads of the conventional semiconductor devices and wires used in a wire bonding operation. The copper leads may be buffed and plated with lead/tin (Pb/Sn) solder. In particular embodiments, such operations are not required be cause wires or solder can be directly attached to the electrically conductive material.

Leadframes in conventional semiconductor devices have a significant amount of surface area in contact with molding compounds. Many molding compounds do not adhere very well to metals or metal alloys used in leadframe. In embodiments described herein, a leadframe is not used, and therefore, the surface area between metal or metal alloys of the lead and vias is significantly less than if a leadframe were used. Therefore, delamination problems can be significantly reduced when using an embodiment described herein. Also, the coefficient of thermal expansion for metals and metal alloys commonly used for the leadframes in conventional devices is significantly different from the coefficient of thermal expansion for the plastic or other organic material of the package. Embodiments described herein can potentially use an electrically conductive material that has a coefficient of thermal expansion closer to that of the plastic or other organic material within the packaging substrate, the encapsulant, or both.

The concepts described herein can be used with a variety of different packages. An exemplary form of such a package includes a quad flat non-leaded (“QFN”), a ball grid array (“BGA”), a leadless land grid array (“LLGA”), or the like. After reading this specification, skilled artisans will appreciate that other packages can be used with the techniques as previously described.

Many different aspects and embodiments are possible. Some of those aspects and embodiments are described below. After reading this specification, skilled artisans will appreciate that those aspects and embodiments are only illustrative and do not limit the scope of the present invention.

In a first aspect, a process of forming an electronic device can include providing a packaging substrate that includes a first major surface and a second major surface opposite the first major surface, wherein the packaging substrate includes a first unit that corresponds to an area of a packaged semiconductor device, and within the first unit, a first major surface of the packaging substrate is substantially free of an electrical conductor. The process can also include forming a first hole from the first major surface and extending into the packaging substrate, and forming electrically conductive material that includes a first portion and a second portion, wherein the first portion includes a first via that within the first hole, and the second portion includes a first lead that lies along the first major surface of the packaging substrate and overlies and is electrically connected to the first via.

In an embodiment of the first aspect, forming the first hole is performed such that the first hole extends completely to the second major surface, and forming an electrically conductive material is performed such that a third portion of the conductive material includes a second lead that lies along the second major surface of the packaging substrate and underlies and is electrically connected to the first via. In another embodiment, the packaging substrate includes an embedded electrical conductor that is spaced apart from the first major surface and the second major surface, and the first hole extends to the electrical embedded conductor and is spaced apart from the second major surface. The process further includes forming a second hole from the second major surface, wherein the second hole extends to the embedded electrical conductor and is spaced apart from the first major surface. Forming an electrically conductive material further forms a third portion and a fourth portion, wherein the third portion includes a second via that lies within the second hole, and the fourth portion includes a second lead that lies along the second major surface of the packaging substrate and is electrically connected to the first and second vias. In a particular embodiment, the first via extends in a first direction from the first major surface towards the second major surface, the second via extends in a second direction from the second major surface towards the first major surface, and the first direction is laterally offset from the second direction.

In still another embodiment of the first aspect, forming the conductive material includes plating the conductive material. In a particular embodiment, forming the conductive material includes printing a conductive ink before forming the conductive material. In a further embodiment, the packaging substrate includes a plastic material. In a particular embodiment, the plastic material includes a thermally conductive filler.

In yet a further embodiment of the first aspect, the process further includes attaching a die to the packaging substrate with an adhesive compound, wherein the adhesive compound lies between the die and the first via, and encapsulating the die with an encapsulant, wherein substantially no encapsulant is formed between the die and the first via. In another embodiment, the process further includes attaching a die to the packaging substrate, wherein the die includes a bond pad, and wire bonding the bond pad to the electrically conductive material, wherein a bond at the conductive material directly overlies the first via. In still another embodiment,

In still another embodiment of the first aspect, the process further includes attaching a die to packaging substrate, encapsulating the die with an encapsulant, and singulating the packaging substrate into a semiconductor device, wherein during singulating, all electrically conductive components within the first area are spaced apart from the sides of the first unit, wherein the sides are substantially perpendicular to the first and second major surfaces, and wherein singulating is formed such that only an organic material is cut. In a further embodiment, packaging substrate does not include a leadframe. In still a further embodiment, the packing substrate includes acrylonitrile butadiene styrene, polycarbonate, polyamide, polypropylene, polypthalamide, polyester, polyarylamide, polyacetal, polyphenylene oxide, polyetherimide, liquid crystal polymer, fluorine-containing polymer, epoxy molding compound, or any combination thereof. In yet another embodiment, forming the electrically conductive material includes electrolessly plating the electrically conductive material, performing an additive plating process, electroless plating the electrically conductive material, conductive ink printing, or any combination thereof.

In a second aspect, an electronic device can include a packaging substrate that includes a first major surface and a second major surface opposite the first major surface. The packaging substrate can further includes a plastic base material having a first hole therein, wherein the first hole extends from the first major surface into the packaging base material, a first via within the first hole, and a first lead lying along the first major surface of the packaging substrate and electrically connected to the first via. The electronic device can also include a die attached to the packaging substrate, wherein the die includes a bond pad, and an electrical connection between the bond pad and the first lead, wherein the electrical connection is attached to the first lead directly above the first via.

In an embodiment of the second aspect, the electrical connection includes a wire having a first end and a second end opposite the first end, wherein the first end is bonded to the bond pad, and the second end is bonded to the first lead. In another embodiment, the electrical connection includes solder that is extends to the bond pad and the first lead.

In a third aspect, an electronic device can include a packaging substrate. The packaging substrate can include an organic material including a first major surface and a second major surface opposite the first major surface, a first hole from the first major surface and extending into the organic material, and a plated conductor that includes a plated material. The plated conductor can include a first via within the first hole, wherein the plated material substantially fills the hole, and a first lead lying along the first major surface of the packaging substrate and electrically connected to the first via.

In an embodiment of the third aspect, the electronic device further includes a die attached to the packaging substrate, wherein the die includes a bond pad, and an electrical connection between the bond pad and the plated conductor. In a particular embodiment, the electrical connection includes a wire has a first end and a second end opposite the first end, wherein the first end is bonded to the bond pad, and the second end is bonded to the plated conductor

Note that not all of the activities described above in the general description or the examples are required, that a portion of a specific activity may not be required, and that one or more further activities may be performed in addition to those described. Still further, the order in which activities are listed is not necessarily the order in which they are performed.

Certain features are, for clarity, described herein in the context of separate embodiments, may also be provided in combination in a single embodiment. Conversely, various features that are, for brevity, described in the context of a single embodiment, may also be provided separately or in any subcombination. Further, reference to values stated in ranges includes each and every value within that range.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

The specification and illustrations of the embodiments described herein are intended to provide a general understanding of the structure of the various embodiments. The specification and illustrations are not intended to serve as an exhaustive and comprehensive description of all of the elements and features of apparatus and systems that use the structures or methods described herein. Separate embodiments may also be provided in combination in a single embodiment, and conversely, various features that are, for brevity, described in the context of a single embodiment, may also be provided separately or in any subcombination. Further, reference to values stated in ranges includes each and every value within that range. Many other embodiments may be apparent to skilled artisans only after reading this specification. Other embodiments may be used and derived from the disclosure, such that a structural substitution, logical substitution, or another change may be made without departing from the scope of the disclosure. Accordingly, the disclosure is to be regarded as illustrative rather than restrictive.

What is claimed is:

1. A process of forming an electronic device comprising:
providing a packaging substrate that includes a first major surface and a second major surface opposite the first major surface, wherein the packaging substrate includes a first unit that corresponds to an area of a packaged semiconductor device, and within the first unit, a first major surface of the packaging substrate is substantially free of an electrical conductor;
forming a first hole from the first major surface and extending into the packaging substrate; and
forming electrically conductive material that includes a first portion and a second portion, wherein the first portion includes a first via that within the first hole, and the second portion includes a first lead that lies along the first major surface of the packaging substrate and overlies and is electrically connected to the first via.

2. The process of claim 1, wherein:
forming the first hole is performed such that the first hole extends completely to the second major surface; and
forming an electrically conductive material is performed such that a third portion of the conductive material includes a second lead that lies along the second major surface of the packaging substrate and underlies and is electrically connected to the first via.

3. The process of claim 1, wherein:
the packaging substrate includes an embedded electrical conductor that is spaced apart from the first major surface and the second major surface;
the first hole extends to the electrical embedded conductor and is spaced apart from the second major surface;
the process further comprises forming a second hole from the second major surface, wherein the second hole extends to the embedded electrical conductor and is spaced apart from the first major surface; and
forming an electrically conductive material further forms a third portion and a fourth portion, wherein the third portion includes a second via that lies within the second hole, and the fourth portion includes a second lead that lies along the second major surface of the packaging substrate and is electrically connected to the first and second vias.

4. The process of claim 3, wherein:
the first via extends in a first direction from the first major surface towards the second major surface;
the second via extends in a second direction from the second major surface towards the first major surface; and
the first direction is laterally offset from the second direction.

5. The process of claim 1, wherein forming the conductive material comprises plating the conductive material.

6. The process of claim 5, wherein forming the conductive material comprises printing a conductive ink before forming the conductive material.

7. The process of claim 1, wherein the packaging substrate comprises a plastic material.

8. The process of claim 7, wherein the plastic material includes a thermally conductive filler.

9. The process of claim 1, further comprising:
attaching a die to the packaging substrate with an adhesive compound, wherein the adhesive compound lies between the die and the first via; and
encapsulating the die with an encapsulant, wherein substantially no encapsulant is formed between the die and the first via.

10. The process of claim 1, further comprising:
attaching a die to the packaging substrate, wherein the die includes a bond pad; and
wire bonding the bond pad to the electrically conductive material, wherein a bond at the conductive material directly overlies the first via.

11. The process of claim 1, further comprising:
attaching a die to packaging substrate;
encapsulating the die with an encapsulant; and
singulating the packaging substrate into a semiconductor device, wherein during singulating, all electrically conductive components within the first area are spaced apart from the sides of the first unit, wherein the sides are substantially perpendicular to the first and second major surfaces, and wherein singulating is formed such that only an organic material is cut.

12. The process of claim 1, wherein packaging substrate does not include a leadframe.

13. The process of claim 1, wherein the packing substrate includes acrylonitrile butadiene styrene, polycarbonate, polyamide, polypropylene, polypthalamide, polyester, polyarylamide, polyacetal, polyphenylene oxide, polyetherimide, liquid crystal polymer, fluorine-containing polymer, epoxy molding compound, or any combination thereof.

14. The process of claim 1, wherein forming the electrically conductive material comprises:
electrolessly plating the electrically conductive material;
performing an additive plating process;
electroless plating the electrically conductive material;
conductive ink printing; or
any combination thereof.

15. An electronic device comprising:
a packaging substrate including a first major surface and a second major surface opposite the first major surface, wherein the packaging substrate further includes:
a plastic base material having a first hole therein, wherein the first hole extends from the first major surface into the packaging base material;
a first via within the first hole; and
a first lead lying along the first major surface of the packaging substrate and electrically connected to the first via;
a die attached to the packaging substrate, wherein the die includes a bond pad; and
an electrical connection between the bond pad and the first lead, wherein the electrical connection is attached to the first lead directly above the first via.

16. The electronic device of claim 15, wherein the electrical connection comprises a wire having a first end and a second end opposite the first end, wherein the first end is bonded to the bond pad, and the second end is bonded to the first lead.

17. The electronic device of claim 15, wherein the electrical connection comprises solder that is extends to the bond pad and the first lead.

18. An electronic device comprising:
a packaging substrate comprising:
an organic material including a first major surface and a second major surface opposite the first major surface;
a first hole from the first major surface and extending into the organic material;
a plated conductor that includes a plated material, wherein the plated conductor comprises:
a first via within the first hole, wherein the plated material substantially fills the hole; and
a first lead lying along the first major surface of the packaging substrate and electrically connected to the first via.

19. The electronic device of claim 18, further comprising:
a die attached to the packaging substrate, wherein the die includes a bond pad; and
an electrical connection between the bond pad and the plated conductor.

20. The electronic device of claim 19, wherein the electrical connection comprises a wire has a first end and a second end opposite the first end, wherein the first end is bonded to the bond pad, and the second end is bonded to the plated conductor.
